(19) United States
(12) Patent Application Publication
(10) Pub. No.: US 2014/0333329 A1
(43) Pub. Date: Nov. 13, 2014

(54) METHOD AND APPARATUS FOR MEASURING THICKNESS OF LAYER IN PRINTED CIRCUIT BOARD

(71) Applicant: AVAGO TECHNOLOGIES GENERAL IP (SINGAPORE) PTE. LTD., Singapore (SG)

(72) Inventors: Jin JEONG, Kyunggi province (KR); Chris CHUNG, Seoul (KR); Tae Eun KIM, Gyeonggi-do (KR)

(73) Assignee: Avago Technologies General IP (Singapore) Pte. Ltd ., Singapore (SG)

(21) Appl. No.: 13/890,508

(22) Filed: May 9, 2013

(51) Int. Cl. H05K 1/02; G01B 7/06

(52) U.S. Cl. CPC H05K 1/0268; G01B 7/08
USPC 324/671; 361/748

(57) ABSTRACT

A method for testing an electronic device comprises providing a device under test (DUT) defined on a printed circuit board (PCB). The DUT includes a measurement target layer forming part of the PCB, and a transmission line which is in contact with the measurement target layer. The method further comprises applying an electric power to the transmission line, measuring a capacitance of the measurement target layer while the electric power is being applied, and computing a thickness of the measurement target layer based on the measured capacitance.

### BACKGROUND

As is known, printed circuit boards (PCBs) has played an important role in integrating electronic components and circuits for manufacturing various kinds of electronic devices. For instance, the portable communications devices capable of radio frequency (RF) and/or microwave communications (300 MHz-to-3 GHz), such as smart phones as well as older models of mobile phones, are implemented by using PCBs.

Meanwhile, the industry of manufacturing the electronic devices such as the portable communications devices is faced with an increasing demand for smaller devices in their sizes to obtain better usability. In order to meet the demand, it is required to reduce not only the sizes of the PCBs forming parts of the electronic devices, but also the sizes of circuits and pads integrated into the PCBs.

Accordingly, there were continued efforts to develop advanced processing technologies for printing internal and external layers for forming the circuits and the pads of the PCBs. For example, a PCB 100 illustrated in FIG. 10 includes a plurality of devices under test (DUTs), each of which is defined within an area of 5×7.5 mm² on a PCB 100. Within this tiny DUT area, metallic layers M1 to M7 and dielectric material layers D1 to D6 as printed components are printed and stacked up while falling within a range of 20 to 60 μm in their thicknesses by applying the improved printing technologies. Further, electrical components (not shown) surface-mounted components are integrated along a surface of the stacked layers. The PCB 100 as described above is called a multi-layered microstrip PCB, which can be employed, for ultra-high frequency mobile applications (300 MHz-to-3 GHz).

However, despite the improved printing technologies, there has arisen the problem of variation in a thickness of a layer forming part of the PCB, since controllability in printing the layer is not yet sufficient. For example, FIG. 12 shows thicknesses of the dielectric material layers D1 to D6 of the PCB 100 may vary, irrespective of a distance from a reference point.

Moreover, it has been found that the variation in thickness of the layer may seriously affect the characteristics and performance of the PCB and the electronic device including same especially when the layer is formed of dielectric material or insulating material. This is because the thickness variation affects impedance of those components connected to the layer. The relationship between them can be expressed by the following Equations 1 and 2:

Z=R+(jwc)⁻¹ (Equation 1)

c=e×s/d (Equation 2)

where Z, R, j, w, and c represent impedance, a resistance, imaginary unit, radial frequency, and capacitance, respectively and e, s, and d represent relative permittivity, area of a conductive plate of a conductor, and thickness of the dielectric material of the conductor, respectively.

Since the layer of the PCB can be considered as the dielectric material of the capacitor, it can be said that the variation in the thickness d of the dielectric material layer causes variation in the capacitance c according to Equation 2, and variation in the capacitance c affects the impedance Z according to the Equation 1.

In addition, it has been found that the thickness variation in the layer nay cause phase variation and frequency shift of an electric signal passing through the component, as illustrated in FIGS. 13 and 14.

As a result, in manufacturing electronic devices by using the multi-layered microstrip PCB, it has become essential to develop a technology which is capable of accurately measuring the thickness of the dielectric material layer without damaging the PCB, and which is easy and convenient to use in the actual PCB industry, and compatible with various types of electronic devices.

### SUMMARY

It is, therefore, an object of the present teachings to provide a method and apparatus for measuring the thickness of a dielectric material layer in a PCB.

In accordance with a representative embodiment, there is provided a method for testing an electronic device, comprising providing a device under test (DUT) defined on a printed circuit board (PCB), wherein the DUT includes a measurement target layer forming part of the PCB, and a transmission line which is in contact with the measurement target layer, the method further comprising applying an electric power to the transmission line, measuring a capacitance of the measurement target layer while the electric power is being applied, and computing a thickness of the measurement target layer based on the measured capacitance.

In accordance with another embodiment of the present invention, there is provided an apparatus for measuring a thickness of a measurement target layer of a DUT defined on a PCB, the apparatus comprising a connection unit configured to electrically connect the DUT with the apparatus, a capacitance measurement unit configured to apply an electric power to the DUT through the connection unit and measure a capacitance established by the measurement target layer, and a thickness computation unit configured to compute the thickness of the measurement target layer based on the capacitance measured by the capacitance measurement unit.

In accordance with a further embodiment of the present invention, there is provided a PCB on which at least one DUT is formed, the PCB comprising a measurement target layer disposed within the DUT, a transmission line which is in contact with a first surface of the measurement target layer, an electrically conductive layer connected to ground (GND), the electrically conductive layer facing the transmission line and being in contact with a second surface of the measurement target layer, and a contact pad formed on a top of the PCB, the contact pad including an electrically conductive material.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

The above and other objects and features of the present invention will become apparent from the following description of preferred embodiments given in conjunction with the accompanying drawings, in which:

FIG. 1 illustrates a diagram of an apparatus for measuring thickness of a layer of a PCB in accordance with a representative embodiment;

FIGS. 2A and 2B schematically show DUTs in accordance with a representative embodiment;

FIG. 3 depicts an apparatus for testing a PCB in accordance with a representative embodiment;

FIG. 4 describes a flowchart illustrating a method of measuring the thickness of a layer of a PCB in accordance with a representative embodiment;

FIG. 5 shows a flowchart illustrating a method of testing a PCB having multiple dielectric layers in accordance with a representative embodiment;

FIGS. 6A and 6B provide a plan view of a DUT in accordance with a representative embodiment and a diagram illustrating the arrangement thereof on a PCB, respectively;

FIG. 7 is a graph illustrating variation in the capacitance of each dielectric layer over time in accordance with a representative embodiment;

FIG. 8 describes relationship between the yield rate of DUTs and the yield rate of a PCB in accordance with a representative embodiment.

FIG. 9 plots the yield rate and error rate of DUTs attributable to variation in the thicknesses of dielectric layers;

FIGS. 10 and 11 illustrate the sectional structure of a conventional device having multiple dielectric layers and the arrangement thereof on a PCB, respectively;

FIG. 12 is a graph illustrating the relationship between the thickness of a conventional dielectric layer and distance;

FIG. 13 shows variation in phase attributable to variation in the thicknesses of conventional dielectric layers; and

FIG. 14 depicts variation in frequency attributable to variation in the thicknesses of conventional dielectric layers;

### DETAILED DESCRIPTION

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the illustrative embodiments. Such methods and apparati are clearly within the scope of the present teachings.

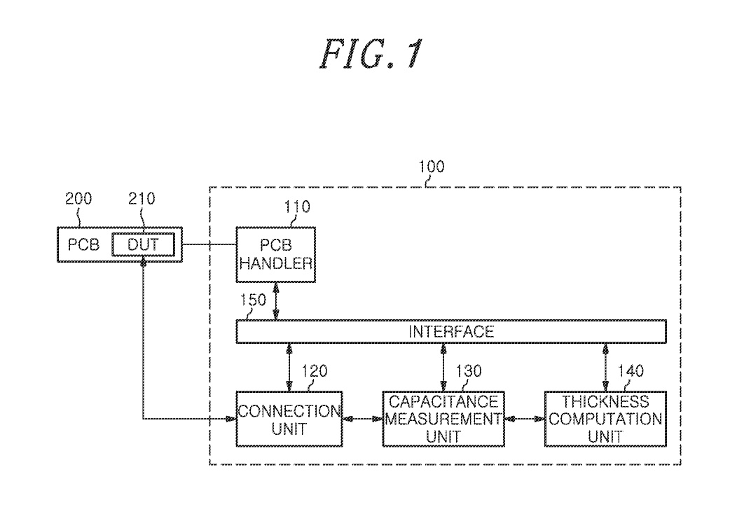

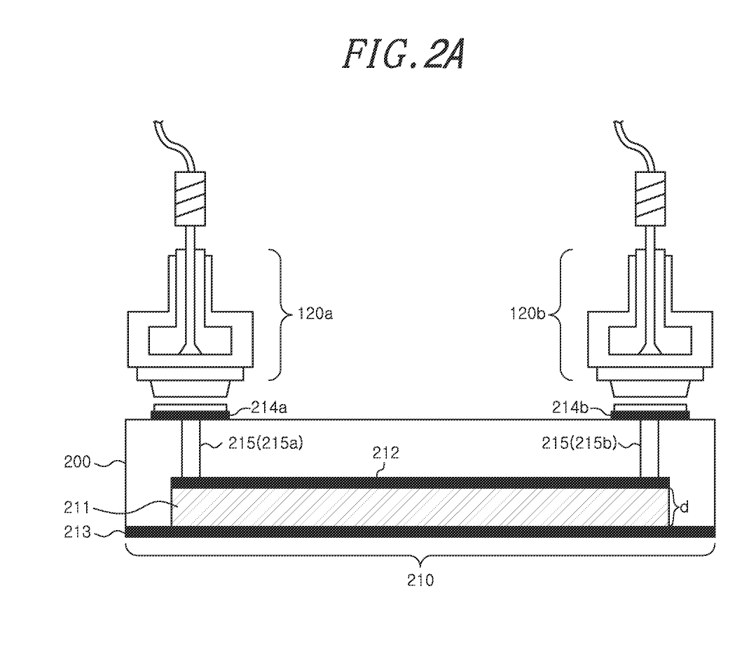

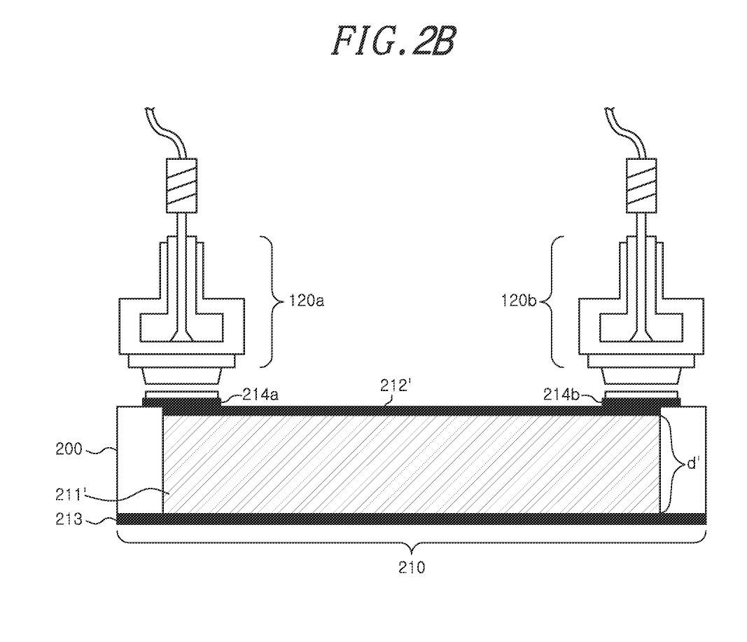

FIGS. 1 to 2B illustrate an apparatus 100 and a PCB processed by the apparatus 100, which are in accordance with a representative embodiment. The PCB 200 is described prior to the apparatus 100 for convenience's sake.

The PCB 200 processed by the apparatus in accordance with the present embodiment is a substrate or a board that is installed inside a variety of types of electronic apparatuses or mechanical apparatuses, and may include all types of boards, such as a single-sided board, a double-sided board, a single layer board and a multi-layer board, regardless of their structure and purpose.

Furthermore, at least one DUT 210 is provided on the PCB 200. The DUT 210 may refer to an area that is defined within part of the PCB 200 and is configured for performing test thereon. Further, the DUT 210 may also refer not only to the area but also a device that is formed in the area and has a measurement target layer 211 which is configured to be tested. In addition, the DUT 210 may include a pattern which is identical to that of a specific area of the PCB 200 outside the DUT 210 and is configured merely to allow its thickness to be measured. In addition, the DUT may be a passive RF/microwave duplexer.

The DUT 210, as illustrated in FIGS. 2A and 2B, may include a measurement target layer 211′, a transmission line (TLIN) 212, a ground 213, a contact pad 214, and preferably, a via 215.

The measurement target layer 211 includes at least one of layers forming the PCB 200, and has a thickness d which is to be measured or computed. The thickness d can be defined as distance between the transmission line 212, 212′ and the ground 213. The measurement target layer 211, 211′ is formed of dielectric material or insulating material, and disposed between the transmission line 212 and the ground 213. The measurement target layer 211, 211′ may be an internal layer of the PCB as illustrated in FIG. 2A or an external layer as illustrated in FIG. 2B.

The transmission line 212 is disposed in contact with part of surface, e.g., upper surface, of the measurement target layer 211, 211′ and is formed of electrically conductive material. The transmission line 212 may be a microstrip line. The transmission line 212 may be disposed inside the PCB 200 as illustrated in FIG. 2A, or on the top of the PCB as illustrated in FIG. 2B.

An electrically conductive layer 213 is connected to ground (GND), i.e., grounded, and is disposed in contact with other part of the surface, e.g., lower surface, of the measurement target layer 211. The electrically conductive layer 213 is called ground hereinafter. The ground 213 faces with the transmission line 212 while interposing the measurement target layer 211.

The contact pad 214 is formed on a top surface of the DUT 210 to be electrically connected to the connection unit 120 of the measuring apparatus 100. The contact pad 214 may include a pair of pads 214a, 214b that include electrically conductive material.

As illustrated in FIG. 2A, the DUT 210 may further include the via 215 formed of electrically conductive material. The via 215 electrically connects the contact pad 214 with the transmission line 212, and a ground 213 disposed on the bottom of the measurement target layer 211. The via 215 may include one or more vias 215a, 215b.

The apparatus 100 for measuring the thickness of a PCB in accordance with this embodiment may include a PCB handler 110, the connection unit 120, a measurement unit 130, a thickness computation unit 140, and an interface 150.

The PCB handler 110 adjusts or maintains a position of PCB. For example, before the measurement of the thickness of the PCB 200, the PCB handler 110 carries the PCB 200 out of an incoming cassette (not illustrated) containing a plurality of measurement target PCBs, and aligns the PCB 200 so that the DUT 210 can be accurately connected to the connection unit 120 of the measuring apparatus 100.

The connection unit 120 electrically connects the measuring apparatus 100 and the PCB 200. For example, as shown in FIGS. 2A and 2B, the connection unit 120 may include a pair of probes 120a, 120b which are in contact with a first and a second pad 214a, 214b of the contact pad 214 of the PCB 200.

The capacitance measurement unit 130′ applies preset power to the transmission line 212, 212′ in a form of an electrical signal such as radio frequency or microwave through the connection unit 120 electrically connected to the contact pad 214 on the DUT 210, and measures a capacitance value that is established in the corresponding measurement target layer 211, 211′ as the power is applied. Here, the connection unit 120 may include at least one RF probe that is connected to the contact pad 214 and inputs the power applied by the measurement unit 130 into the transmission line 212, 212′ of the measurement target layer 211, 211′.

The thickness computation unit 140 computes the thickness of the corresponding measurement target layer 211, 211′ using the capacitance value of the measurement target layer 211, 211′ of the PCB 200, which is measured by the capacitance measurement unit 130′.

That is, the thickness computation unit 140 receives the capacitance value of the measurement target layer 211, 211′, and computes the thickness of the measurement target layer 211, 211′ based on the received capacitance value. In this case, since capacitance value can be calculated based on the aforementioned Equation 2, and the relative permeability e and the capacitor conductor area s are constant, the thickness computation unit 140 can compute the thickness d of the corresponding measurement target layer 211, 211′ based on the measurement of the capacitance value of the measurement target layer 211, 211′.

Furthermore, the thickness computation unit 140 may determine whether the PCB 200 is a desirable product or not by comparing the calculated thickness of the measurement target layer 211 with a preset reference value. For example, if the computed thickness falls within a preset numerical range, the corresponding PCB 200 may be determined to belong to a passed group. In contrast, if the computed thickness is out of the preset numerical range, the corresponding PCB 200 may be determined to belong to a failed group.

In addition, the PCB handler 110, the measurement unit 130, and the thickness computation unit 140 may be connected to each other via an interface, such as a General Purpose Interface Bus (GPIB), and then exchange signals or data therebetween.

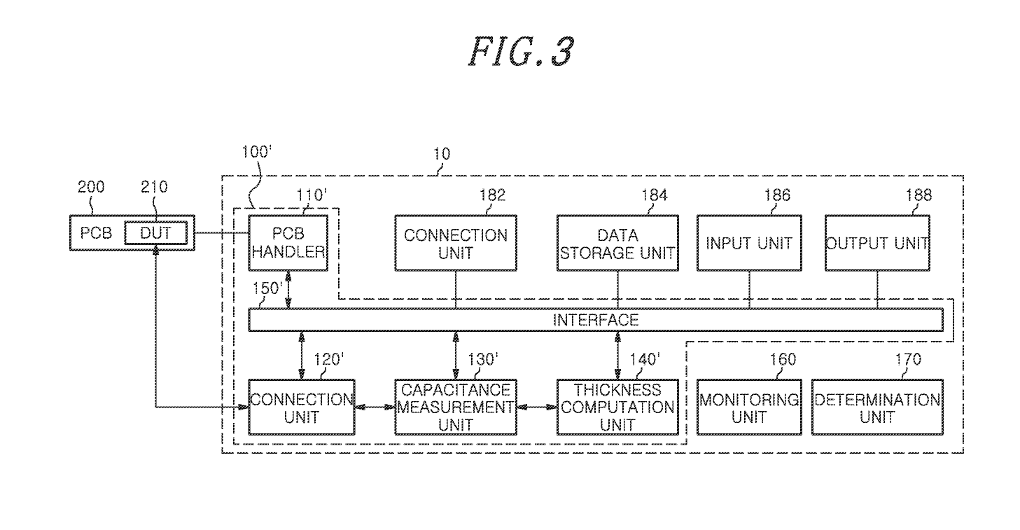

FIG. 3 is a system 10 for testing a PCB 200 and/or a DUT 210 in accordance with one embodiment of the present invention.

Referring to FIG. 3, the system 10 includes a PCB handler 110′, a connection unit 120′, a capacitance measurement unit 130′, a thickness computation unit 140′, and an interface 150′ that are substantially identical to that of the measuring apparatus 100 as described above. In other embodiments, these units may be implemented by the measuring apparatus 100. Accordingly, description about identical portions of these units is omitted.

The system 10 further includes a monitoring unit 160, a determination unit 170, a control unit 182, a data storage unit 184, an input unit 186, and an output unit 188.

The monitoring unit 160 is configured to monitor change of the capacitance measured by the capacitance measurement unit 130′ or the thickness computed by the thickness the thickness computation unit 140′ through time. Then, the monitoring unit computes and outputs variation in the thickness or the capacitance. In some embodiments, the monitoring unit 160 may be implemented by a high-precision vector network analyzer up to 50 GHz.

The determination unit 170 is configured to compare the variation output from the monitoring unit 160 with a predetermined threshold value, and determine whether or not the DUT 210 is desirable one. Alternatively, the determination unit 170 may determine whether or not the PCB 200 is desirable one.

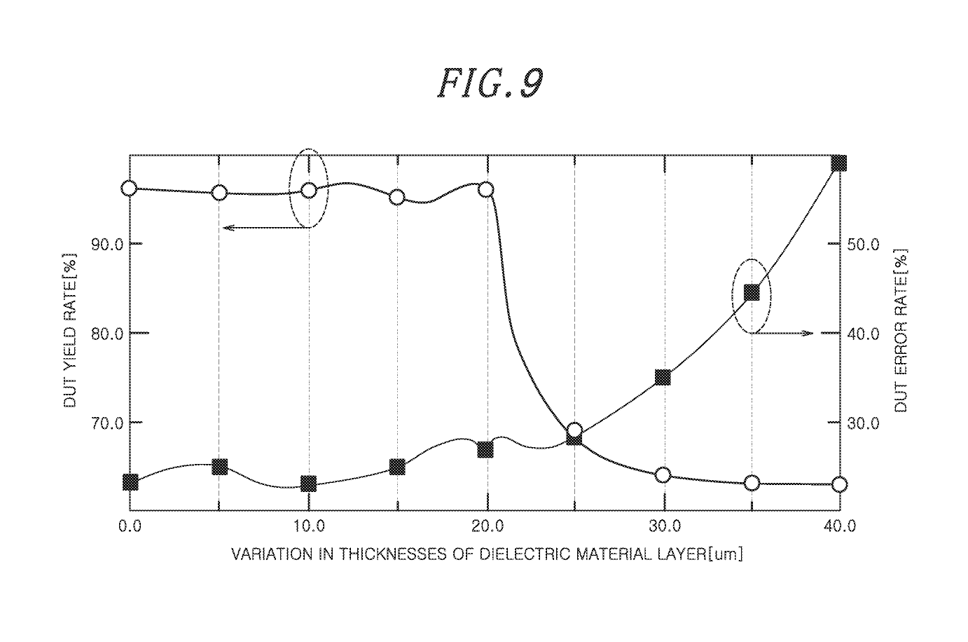

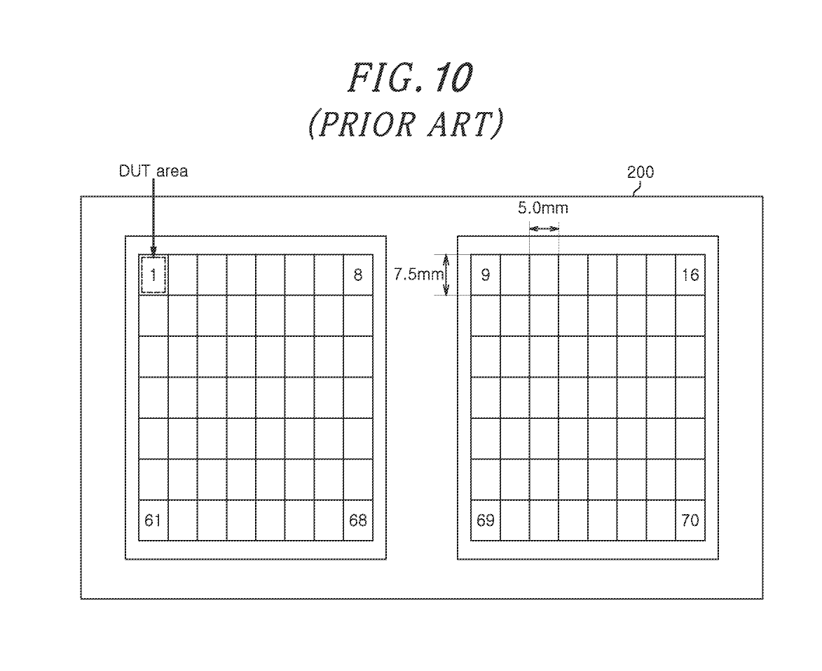

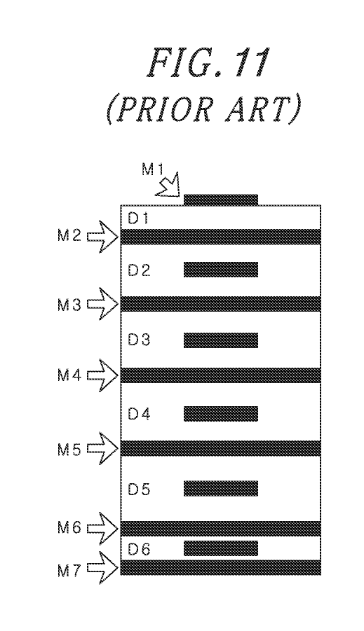

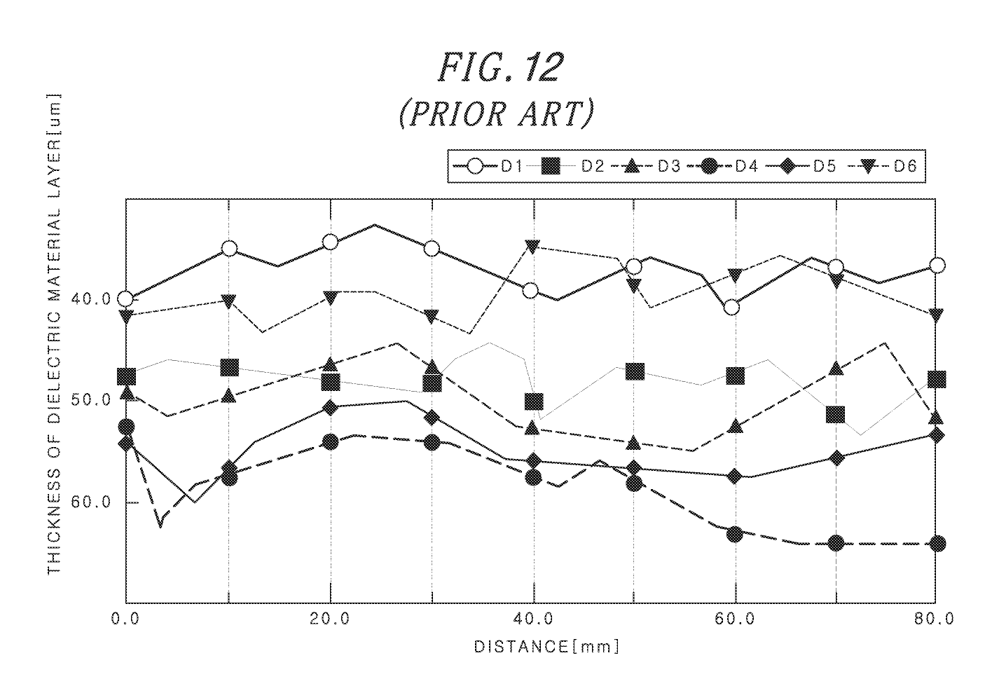

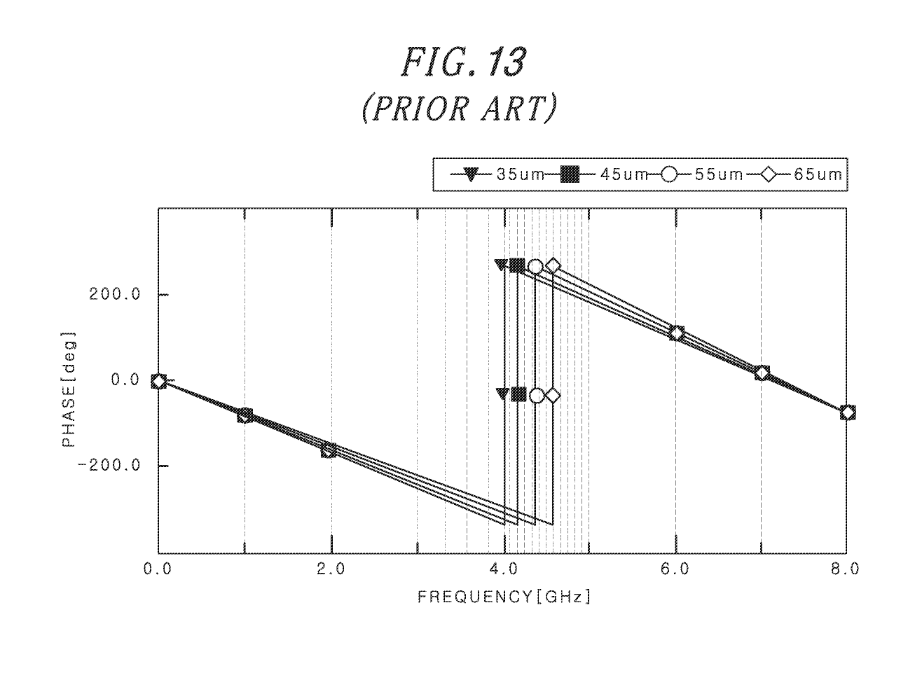

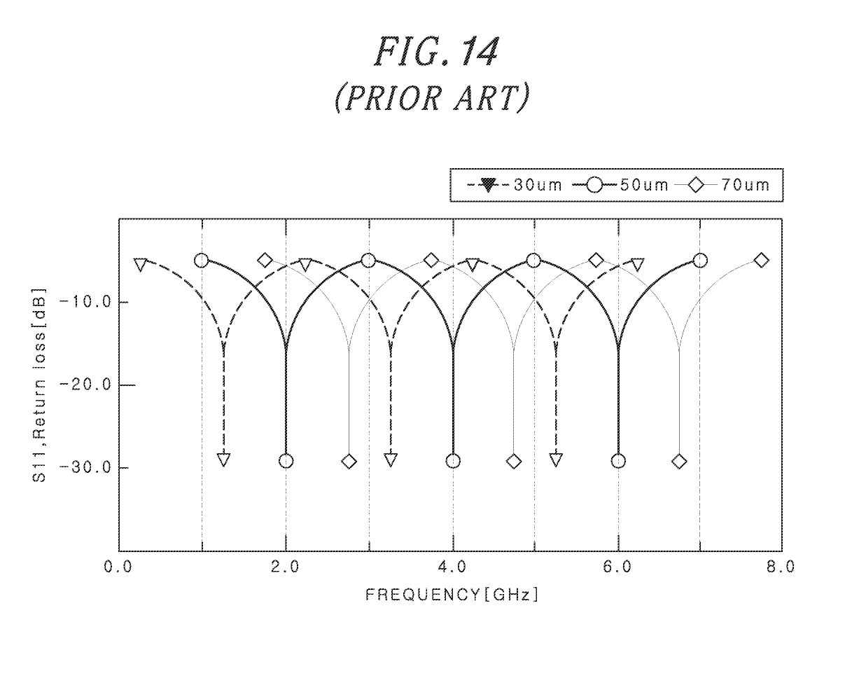

Referring to FIG. 9, it can be seen that the yield rate of the DUTs having multiple dielectric layers decreases sharply after the variation in the thicknesses of dielectric layers has exceeded 20 μm, and the error rate thereof increases in geometrical progression. Accordingly, the threshold value for said determining can be set as 20 μm. In addition, the yield rate and the error rate of DUTs was calculated according to the following Equations 3 and 4:

DUT yield rate (%)=[the number of DUTs with error rate less than 10%]/[total number of DUTs] (Equation 3)

Error rate (%)=([targeted output power (dB)]−[measured output power (dB)])/[input power (dB)] (Equation 4)

Turning back to FIG. 3, the data storage unit 182 stores data used in operations of the components of the system 10.

The input unit 186 receives data for the operations of the system 10 or instruction from a user. For example, the data may include the threshold value for determination function of the determination unit 170. Further, the instruction may include a command for starting or stopping the test.

The output unit 188 outputs data for the operations of the system 10 or the test result output from the components of the system 10. For example, the output unit 188 includes a screen configured to display the change of the measured capacitance in real time.

The control unit 182 is configured to control the respective components of the system 10 so that the system 10 performs test. For example, data exchanges between the respective components through the interface 150′ may be controlled by the control unit. Further, the PCB handler may be automatically operable by the control unit.

In another embodiment, at least part of the components of the system 10 may be implemented by a general purpose computer, such as desktop PC and laptop which has a CPU, memory, and peripheral device.

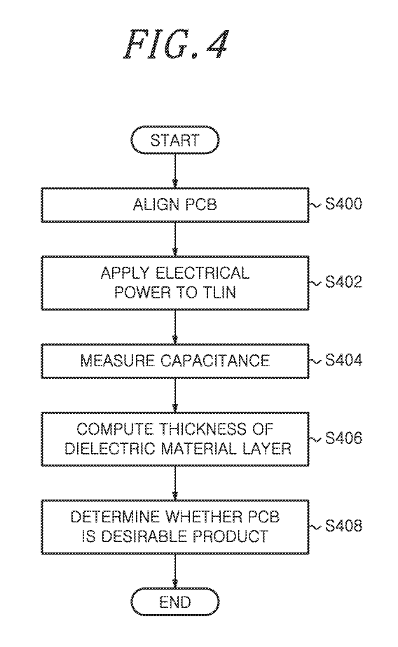

FIG. 4 is a flowchart illustrating a method of measuring the thickness of a PCB 200 having multiple dielectric layers in accordance with a representative embodiment. This method may be performed using the apparatus 100 as illustrated in FIG. 1 or the system as illustrated in FIG. 3.

At first, the PCB 200 is moved and aligned to a predetermined position suitable for the measurement (step S400). In case the step S400 is performed by the measuring apparatus 100 or by the system 10, the PCB handler 110, 110′ carries the PCB 200 out of an incoming cassette (not illustrated), and aligns the PCB 200 so that the DUT 210, can accurately contact to the connection unit 120, 120′ of the measuring apparatus 100, 100′. For example, the PCB handler 110, 110′ may align the PCB 200 by rotating the PCB 200 or moving the PCB 200 in a lateral or vertical direction in order to locate an RF probe of the connection unit 120, 120′ onto the contact pad 214 on the top of the DUT 210 of the PCB 200.

Thereafter, at step S402, an electrical power such as RF/microwave is applied to the transmission line 212, 212′ of the PCB 200. In case the step S402 is performed by the measuring apparatus 100 or by the system 10, the capacitance measurement unit 130′ applies the preset power to the transmission line 212, 212′ on the measurement target layer 211, 211′ inside the DUT 210, using the connection unit 120, 120′, such as an RF probe, electrically connected to the contact pad 214 on the DUT 210.

Then, at step S404, a capacitance value established in the measurement target layer 211, 211′ as the power is applied is measured. In case the step S404 is performed by the measuring apparatus 100 or by the system 10, the capacitance measurement unit 130′ also may be performing the measurement of the capacitance value.

Once the capacitance value established in the measurement target layer 211, 211′ of the DUT 100 has been measured using the capacitance measurement unit 130′, the thickness of the measurement target layer 211, 211′ is computed (step S406). The computation may be based on Equation 2 and the relative permeability e and the capacitor conductor area s are constant which are given in advance. In case the step S406 is performed by the measuring apparatus 100 or by the system 10, the thickness computation unit 140, 140′ computes the thickness of the corresponding measurement target layer 211, 211′ using the capacitance value of the measurement target layer 211, 211′ of the PCB 200 at step S406.

Thereafter, at step S408, determination on whether the PCB is a desirable product or not is performed based on the computed thickness, and the PCB 200 is classified into passed or failed unit depending on the result of the determination. For example, the determination can be performed by comparing the calculated thickness of the measurement target layer 211, 211′ with a preset reference value, e.g., 20 μm. For example, the thickness computation unit 140 may determine the corresponding PCB 200 to belong to a passed group if the computed thickness falls within a preset numerical range, and determine the corresponding PCB 200 to belong to a failed group if the computed thickness is out of the preset numerical range. Further, in case the step S406 is performed by the measuring apparatus 100 or by the system 10, the thickness computation unit 140, 140′ determines whether the PCB 200 is a desirable product or not.

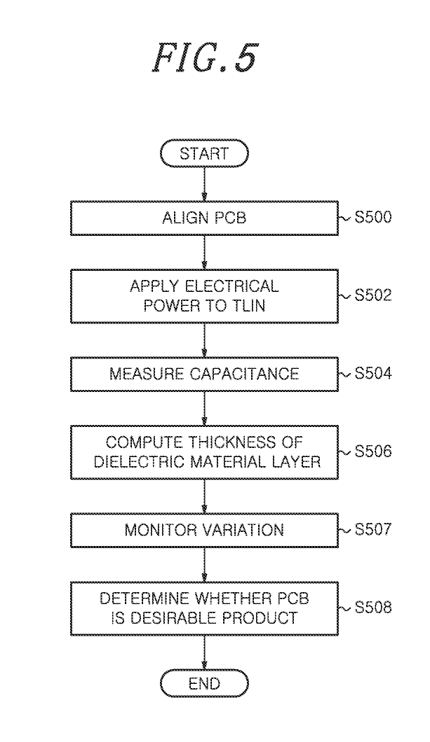

Meanwhile, FIG. 5 is a flowchart illustrating a method of testing a PCB 200 and/or a DUT 210 having multiple dielectric layers in accordance with a representative embodiment. This method may be performed using the system 10 for testing the thickness of a PCB 200 and/or DUT 210 as illustrated in FIG. 3.

Referring to FIG. 5, the test method includes the steps S500 to S506, that are substantially identical to the steps S400 to S406 of the method illustrated in FIG. 4. Accordingly, description about identical portions of these steps is omitted.

The testing method further includes steps S507 and S508.

At step S507, the monitoring unit 160 of the system 10 monitors changes of the measured capacitance or the computed thickness of the measurement target layer for a specific period of time which is preset to e.g., 400 nsec. Then, the monitoring 170 unit outputs variation in the measured capacitance or the computed thickness based on the monitored change.

At step S508, the determination unit 170 of system 10 compares the variation output from the monitoring unit 160 with a threshold value, and determines whether or not the PCB 200 and/or the DUT 210 is desirable one. Specifically, if the variation is greater than the threshold value, the PCB 200 and/or the DUT 210 is considered as desired one, while it is not, otherwise.

Using the above-described methods, the measurement of thickness of a desired layer of a PCB and the test of the PCB can be performed accurately, rapidly, and with ease, regardless of type or structure of the PCB, and without any accompanying damage being caused to the PCB. Especially, these methods can be applicable only by forming a structure described with respect to FIGS. 2A and 2B within the DUT area of the PCB.

In addition, although the method of measuring the thickness of at least one measurement target layer of a single PCB has been described above, it is evident that the thickness of at least one measurement target layer of each of a plurality of PCBs can be rapidly and automatically measured by repeating the above method.

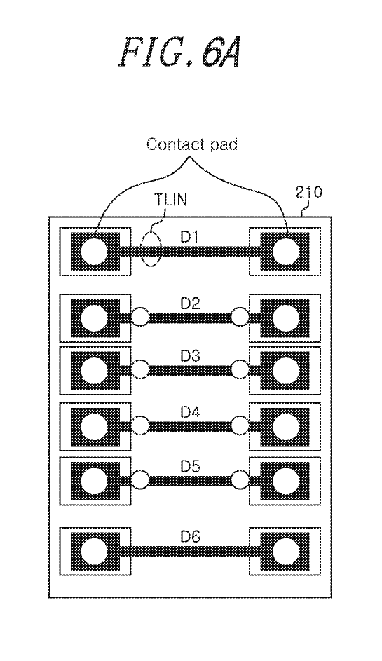

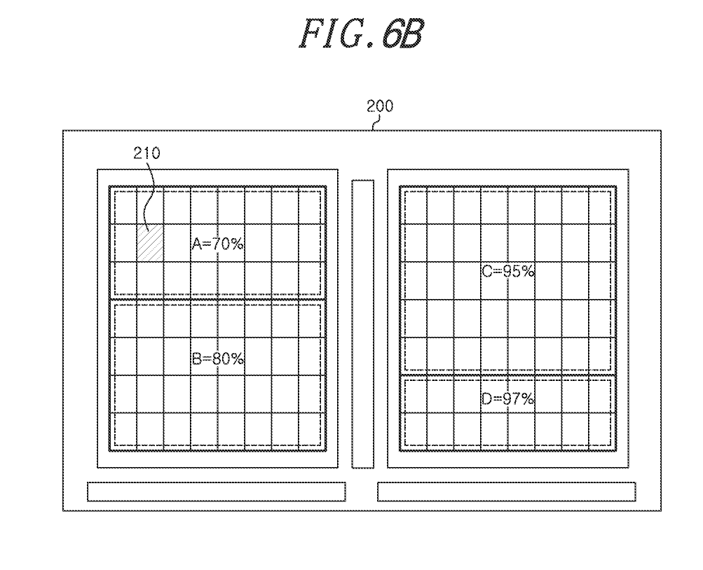

FIGS. 6A and 6B illustrate a plan view of a DUT 210 having multiple dielectric layers in accordance with a representative embodiment and the yield rate of a PCB for each session, respectively. Since structure and cross-section view of each of the dielectric layers D1 to D6 might be substantially identical to those illustrated in FIG. 2A or 2B, the cross-section views of theses dielectric layers D1 to D6 are omitted for the convenience's sake.

Referring to FIG. 6A, it can be seen that the DUT 210 includes contact pads configured to allow the capacitance values of multiple dielectric layers D1 to D6 to be measured, and internal transmission lines TLIN.

That is, the apparatus 100 for measuring the thickness of a PCB measures the capacitance values of the respective dielectric layers D1 to D6 using the contact pads 214 that are connected to the respective dielectric layers D1 to D6 inside the DUT 210 having multiple dielectric layers through the internal transmission lines TLINs and vias. Thereafter, the thicknesses of the respective dielectric layers are computed using the measured capacitance values.

Here, a PCB having multiple dielectric layers may be determined to be a desirable product and then classified as belonging to a passed group, or may be determined to be a defective product and classified as belonging to a failed group based on the range of variations in the thicknesses of dielectric layers. In this case, if the variation in the thicknesses of dielectric layers is out of a preset numerical range, there is a strong possibility that the corresponding PCB belongs to the failed group.

FIG. 6B illustrates the yield rate of 112 products that use PCB boards having multiple dielectric layers.

Referring to FIG. 6B, in order to determine the yield rate of desirable PCB products in a single PCB 900 corresponding to standard variation in the thicknesses of dielectric layers, four major sessions labeled “A,” “B,” “C,” and “D” may be set up. Here, the 4 major sessions refer to 4 groups into which finished products using a PCB are divided. % that is indicated in each area refers to the percentage of desirable products that are identified using only PCB thickness in a DUT present in a single sheet of PCB that is used to verify the performance of the apparatus for measuring thickness in accordance with the present invention, and also refers to the yield rate of the corresponding products.

In this case, for example, when the thickness of each of the dielectric layers D1 to D6 does not deviate from an error rate range of −15 to +15 μm upon determining whether a product in question is a desirable product or not through the measurement of the thickness of a PCB, it may be possible to determine the product in question to be a desirable product. In order to ensure the reliability of the accuracy of the identification of a desirable product, the difference between a PCB thickness value electrically measured using the apparatus for measuring thickness and an actually measured physical thickness value must fall within an error range that is equal to or less than a reference value.

Furthermore, in accordance with the present invention, in order to ensure the reliability of the performance of the apparatus for measuring thickness, a process of computing and recording the electrically measured thickness value of a selected PCB, cutting the corresponding PCB along the side of a specific area, physically and actually measuring the thickness of each dielectric layer, and comparing the two values with each other is performed.

That is, as a result of testing the yield rate of a single PCB illustrated in FIG. 6B, it was verified that the measured yield rate of the PCB was consistent with the measured yield rate of DUTs. This means that, for example, if a PCB is manufactured to have the thicknesses of dielectric layers that fall within a normal range of variations in thickness, the DUTs of the PCB can exhibit a desirable yield rate.

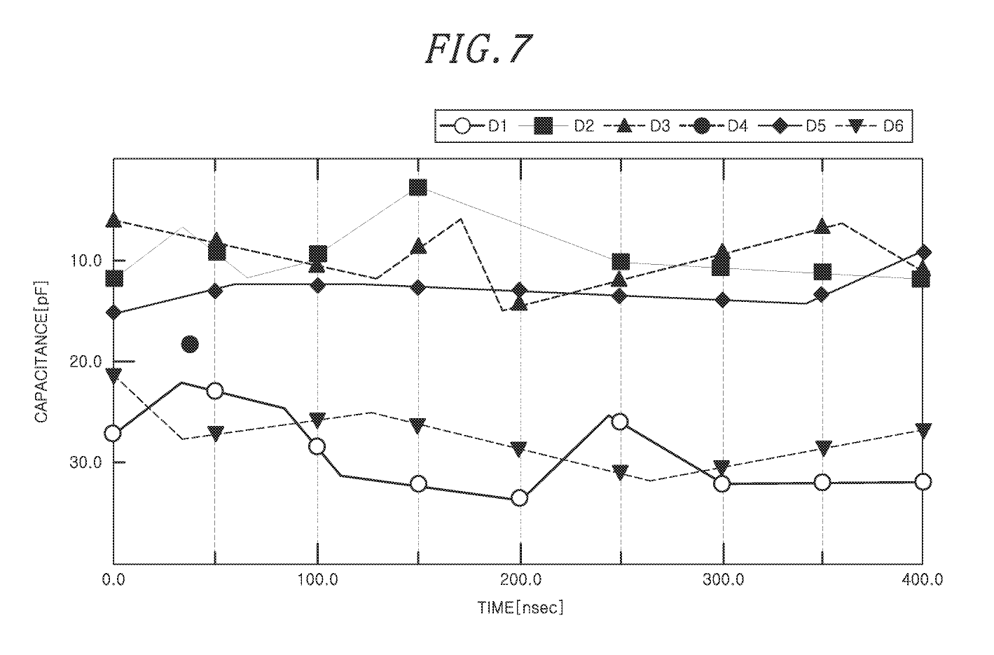

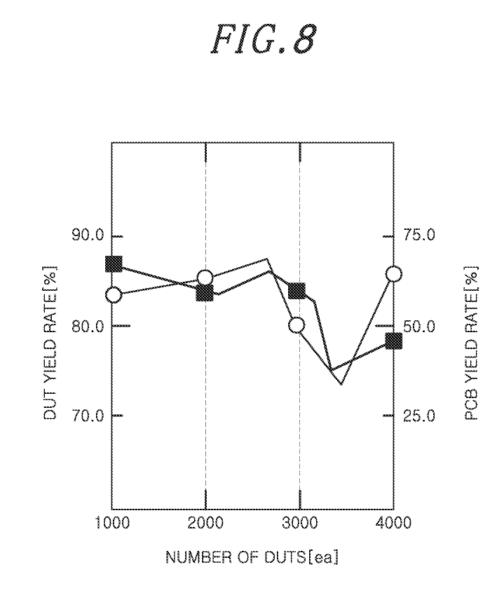

FIG. 7 is a graph illustrating variation in the capacitance of each dielectric layer of a DUT having multiple dielectric layers over time, and FIG. 8 is a graph illustrating the yield rate of DUTs and the yield rate of a PCB in accordance with a representative embodiment.

As shown in FIG. 8, it can be seen that the yield rate of DUTs determined to be normal as a result of measuring the thicknesses of dielectric layers in the DUTs using the apparatus 100 for measuring the thickness of a PCB and the yield rate of a PCB belonging to an actual passed group are satisfactorily consistent with the yield rate of the DUTs determined to be normal as a result of actually measuring the thicknesses of the dielectric layers and the actual yield rate of the PCB.

As a result, it can be verified that the results of measuring the thicknesses of the dielectric layers of the PCB having multiple dielectric layers using the DUT are reliable.

As described above, in accordance with the present teachings, in the measurement of the thicknesses of the dielectric layers inside the microstrip PCB having multiple dielectric layers, the transmission lines are formed on the tops of the respective dielectric layers inside the PCB, the transmission lines are connected to the RF probe connected to external power through vias, and then capacitance is measured in each of the dielectric layers, thereby enabling the thickness of each of the dielectric layers to be accurately measured.

As is apparent from the above description, a method and apparatus for measuring the thickness of a dielectric material layer in a PCB are described. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

What is claimed is:

1. A method for testing an electronic device, comprising:
providing a device under test (DUT) defined on a printed circuit board (PCB), wherein the DUT includes a measurement target layer forming part of the PCB and further includes a transmission line which is in contact with the measurement target layer,
applying an electric power to the transmission line;
measuring a capacitance of the measurement target layer while the electric power is being applied; and
computing thickness of the measurement target layer based on the measured capacitance.

2. The method of claim 1, further comprising:
monitoring a variation in the measured capacitance over time; and
computing a variation in the thickness by using the monitored variation in the measured capacitance.

3. The method of claim 1, further comprising:
determining whether the PCB is a desirable product or not by comparing the computed thickness of the measurement target layer with a threshold value.

4. The method of claim 2, further comprising:
determining whether the PCB is a desirable product or not by comparing the computed variation in the thickness of the measurement target layer with a predetermined value.

5. The method of claim 1, wherein the DUT further includes a contact pad which is electrically connected to the transmission line, and
wherein the electric power is applied through the contact pad.

6. The method of claim 5, wherein the DUT further includes a via for electrically connecting the contact pad and the transmission line, the via being formed of a conductive material.

7. The method of claim 1, wherein the transmission line is a microstrip transmission line.

8. The method of claim 1, wherein the measurement target layer is formed of a dielectric material or an insulating material.

9. An apparatus for measuring a thickness of a measurement target layer of a device under test (DUT) defined on a printed circuit board (PCB), the apparatus comprising:
a connection unit configured to electrically connect the DUT with the apparatus:
a capacitance measurement unit configured to apply an electric power to the DUT through the connection unit and measure a capacitance established by the measurement target layer; and
a thickness computation unit configured to compute a thickness of the measurement target layer based on the capacitance measured by the capacitance measurement unit.

10. The apparatus of claim 9, wherein the connection unit includes a radio frequency (RF) probe connected to a contact pad of the DUT.

11. The apparatus of claim 9, further comprising a PCB handler configured to align the PCB so that the connection unit is located on the contact pad of the DUT.

12. A printed circuit board (PCB) on which at least one device under test (DUT) is formed, the PCB comprising:
a measurement target layer disposed within the DUT;
a transmission line which is in contact with a first surface of the measurement target layer;
an electrically conductive layer connected to ground (GND), wherein the electrically conductive layer faces the transmission line and is in contact with a second surface of the measurement target layer; and
a contact pad formed on a top of the PCB, the contact pad including an electrically conductive material.

13. The PCB of claim 12, wherein the DUT includes a pattern configured to allow the thickness of the PCB to be measured, the pattern having the measurement target layer and having identical shape to that of a specific area of the PCB outside the DUT.

14. The PCB of claim 12, wherein the transmission line is a microstrip transmission line.

15. The PCB of claim 12, wherein the measurement target layer is formed of a dielectric material or an insulating material.

16. The PCB of claim 12, further comprising:
a via electrically connecting the contact pad with the transmission line.
